(19) United States
(12) Patent Application Publication
(10) Pub. No.: US 2022/0013513 A1
(43) Pub. Date: Jan. 13, 2022

(54) ELECTRONIC DEVICE

(71) Applicant: GIO Optoelectronics Corp, Tainan City (TW)

(72) Inventor: Chin-Tang LI, Tainan City (TW)

(21) Appl. No.: 17/366,710

(22) Filed: Jul. 2, 2021

(30) Foreign Application Priority Data
Jul. 7, 2020 (TW) 109122908

(51) Int. Cl. H01L 25/16; H01L 27/12; H01L 23/538

(52) U.S. Cl. CPC H01L 25/167; H01L 23/5385; H01L 27/1214

(57) ABSTRACT

An electronic device includes a circuit board, a plurality of carrier boards, a plurality of photoelectric elements, and a plurality of driving elements. The circuit board has a first conductive layer. The carrier boards are arranged on the circuit board with a component distance in a direction. Each carrier board has a substrate and a second conductive layer. The second conductive layer is disposed on the substrate and electrically connected to the first conductive layer of the circuit board. The substrate defines a substrate area, and each photoelectric element defines an element area. The ratio of the substrate area to the element area is not less than 5. The driving elements are disposed on the circuit board or the carrier boards. The driving elements are electrically connected to the first conductive layer and the second conductive layers, and drive the photoelectric elements.

### CROSS REFERENCE TO RELATED APPLICATIONS

This Non-provisional application claims priority under 35 U.S.C. § 119(a) on Patent Application No(s). 109122908 filed in Taiwan, Republic of China on Jul. 7, 2020, the entire contents of which are hereby incorporated by reference.

### BACKGROUND

### Technology Field

The present disclosure relates to an electronic device and, in particular, to an electronic device with a novel model.

### Description of Related Art

In the conventional manufacture process of electronic device, it is generally to form multiple thin-film transistors on a substrate to obtain a thin-film transistor substrate, and then to utilize the thin-film transistors to drive corresponding electrical elements. Taking the organic light-emitting diode display device of the photoelectric device as an example, when adopting this method of using thin-film transistors to drive the organic light-emitting diodes to emit light, in order to fabricate multiple products with different product sizes or functions, different thin-film processes must be designed respectively for various types of organic light-emitting diode devices (different sizes or functions). Moreover, the expensive thin-film transistor processes, photo masks, substrates, and/or materials are required. Therefore, the conventional manufacture process is not conducive to the needs of diverse products, and the application thereof is quite inflexible.

### SUMMARY

One or more exemplary embodiment of this disclosure is to provide an electronic device that has the application flexibility for reflecting the requirements of users.

In an exemplary embodiment, an electronic device comprises a circuit board, a plurality of carrier boards, a plurality of photoelectric elements, and a plurality of driving elements. The circuit board has a first conductive layer. The carrier boards are arranged on the circuit board with a component distance in a direction. Each carrier board has a substrate and a second conductive layer. The second conductive layer is disposed on the substrate and electrically connected to the first conductive layer of the circuit board. The substrate defines a substrate area. The photoelectric elements are disposed on the carrier boards and electrically connected to the second conductive layers of the carrier boards. Each photoelectric element defines an element area, and the ratio of the substrate area to the element area is not less than 5. The driving elements are disposed on the circuit board or the carrier boards. The driving elements are electrically connected to the first conductive layer and the second conductive layers, and drive the photoelectric elements.

In one embodiment, the ratio of the substrate area to the element area is not less than 50.

In one embodiment, the ratio of the substrate area to the element area is not less than 100.

In one embodiment, the scale of each substrate is defined as one substrate width, and the substrate width is not greater than 10 mm.

In one embodiment, the substrate width is not greater than 5 mm.

In one embodiment, the substrate width is not less than 1 mil.

In one embodiment, the scale each photoelectric element is defined as one element width, and the element width is not greater than 80 mil.

In one embodiment, the element width is not greater than 12 mil.

In one embodiment, the element width is not less than 0.005 mm.

In one embodiment, the component distance is not greater than 10 mm.

In one embodiment, the ratio of the component distance to the substrate width is greater than or equal to 1 and less than or equal to 400.

In one embodiment, the ratio of the component distance to the substrate width is greater than 7.

In one embodiment, the ratio of the substrate width to the element width is greater than or equal to 1 and less than or equal to 2000.

In one embodiment, the circuit board is a transparent, or/and a flexible circuit board.

In one embodiment, the substrate is a transparent, or/and a flexible substrate.

In one embodiment, the first conductive layer, or/and the second conductive layer comprises a copper conductive layer.

In one embodiment, each driving element comprises at least a thin-film transistor, or a semiconductor IC.

In one embodiment, the electronic device further comprises a plurality of conductive members electrically connecting the carrier boards to the circuit board.

In one embodiment, each conductive member is located between the circuit board and the corresponding carrier board.

In one embodiment, each conductive member connects a top surface of the circuit board and a top surface of the corresponding carrier board.

In one embodiment, each carrier board is defined with two surfaces opposite to each other, and one of the two surfaces configured with the photoelectric elements faces toward the circuit board.

In one embodiment, the driving elements and the carrier boards are disposed on two opposite surfaces of the circuit board, respectively.

As mentioned above, the electronic device of this disclosure comprises a circuit board, a plurality of carrier boards, a plurality of photoelectric elements, and a plurality of driving elements. Due to the arrangements and connections of the circuit board, the carrier boards, the photoelectric elements and the driving components, as well as the feature that the ratio of the substrate area to the element area is not less than 5, the electronic device of this disclosure has the application flexibility for reflecting the requirements of users, so that it can be suitable for various product requirements.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1A is a schematic diagram showing the configuration of an electronic device according to an embodiment of this disclosure.

FIG. 1B is a side view of the electronic device according to the embodiment of this disclosure.

FIG. 2 is atop view of the electronic device according to the embodiment of this disclosure.

FIG. 3 is a schematic diagram showing an electronic device according to another embodiment of this disclosure.

### DETAILED DESCRIPTION OF THE DISCLOSURE

The present disclosure will be apparent from the following detailed description, which proceeds with reference to the accompanying drawings, wherein the same references relate to the same elements.

In order to clearly illustrate the present disclosure, the drawings in the following embodiments are only schematic illustrations, and the sizes and proportions of the components are only for describing the technology of the present disclosure and are not to limit the present disclosure.

The electronic device of this disclosure can be an AM (Active Matrix) or PM (Passive Matrix) electronic device. In the following embodiments, the electronic device is, for example, an AM electronic device.

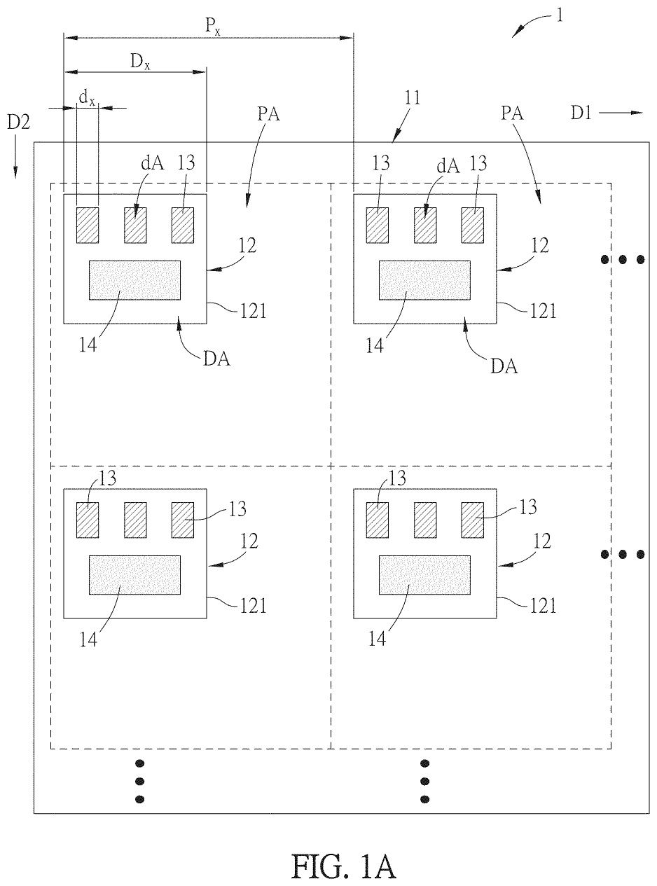

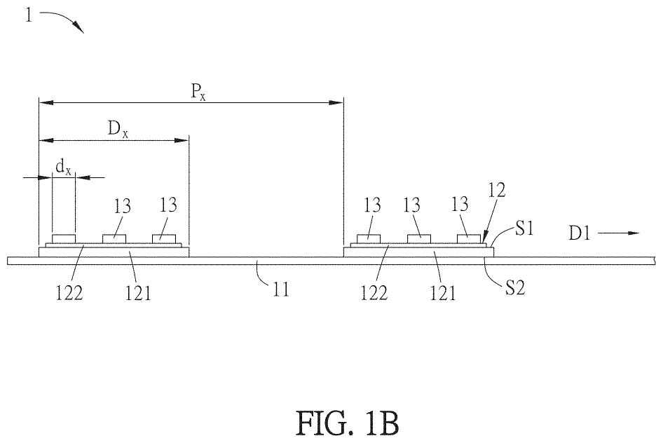

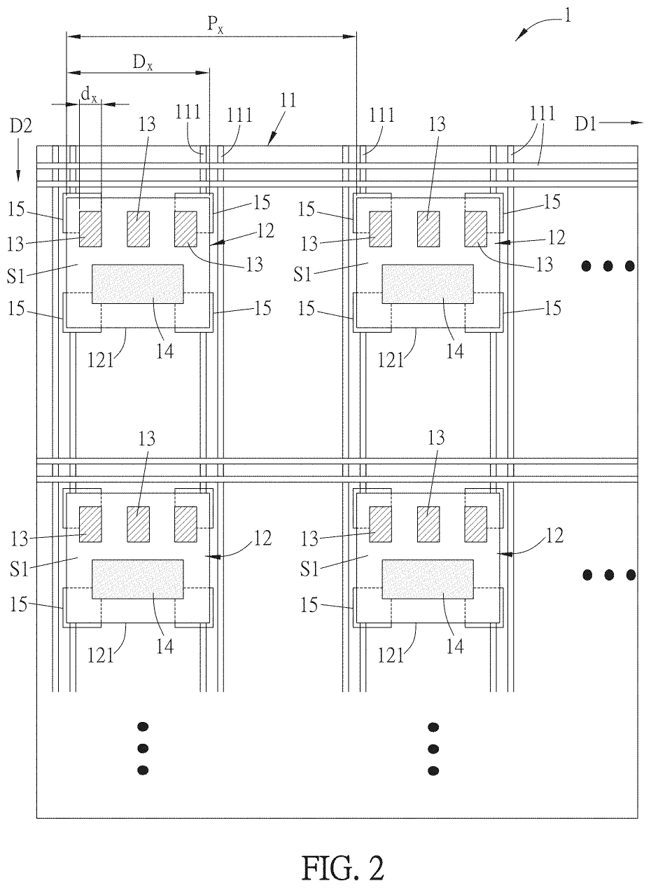

FIG. 1A is a schematic diagram showing the configuration of an electronic device according to an embodiment of this disclosure, FIG. 1B is a side view of the electronic device according to the embodiment of this disclosure, and FIG. 2 is atop view of the electronic device according to the embodiment of this disclosure. Referring to FIGS. 1A to 2, the electronic device 1 comprises a circuit board 11, a plurality of carrier boards 12, a plurality of photoelectric elements 13, and a plurality of driving elements 14. Moreover, the electronic device 1 of this embodiment can further comprise a plurality of conductive members 15. To be noted, FIG. 1A does not show the first conductive layer 111 of the circuit board 11, the second conductive layer 122 of the carrier board 12, and the conductive member 15, FIG. 1B does not show the first conductive layer 111 of the circuit board 11, the conductive member 15, and the driving element 14, and FIG. 2 does not show the second conductive layer 122 of the carrier board 12.

The circuit board 11 comprises a first conductive layer 111 (see FIG. 2). In this embodiment, the first conductive layer 111 comprises a plurality of signal lines. A part of the signal lines are arranged laterally (extending in the direction D1) such as the scan lines, the power lines (Vdd), or the likes. The other part of the signal lines are arranged vertically (extending in the direction D2) and electrically connected to the carrier boards 12, such as the data lines, the ground lines (Vss), or the likes.

The carrier boards 12 are arranged on the circuit board 11 at intervals with a component distance Px in a direction D1. In this embodiment, the carrier boards 12 are arranged in coplanar on the circuit board 11, and adjacent two of the carrier boards 12 are separated with a component distance Px in the direction D1. In addition, the carrier boards 12 are also arranged on the circuit board 11 at intervals with a component distance (which can be equal to the component distance Px) in another direction D2, so that the carrier boards 12 can be arranged in a two-dimensional array. To be noted, this disclosure is not limited thereto. In other embodiments, the carrier boards 12 can be arranged on the circuit board 11 at intervals with a component distance Px in the direction D1 only, or with a component distance (which can be equal to the component distance Px) in the direction D2 only. In this embodiment, the term “component distance Px” indicates the distance between the same lateral sides of adjacent two of the carrier boards 12; to be noted, the lateral side of one carrier board 12 corresponds to another the same lateral side of the other one carrier board 12. To be understood, each component distance Px can define a unit. In some embodiments, the component distance Px can be not greater than 10 mm (i.e., Px≤10 mm), such as 6.2 mm, 4.0 mm, 1.2 mm, 1.0 mm, 0.4 mm, or less than 0.4 mm, or the likes.

Each carrier board 12 has a substrate 121 and a second conductive layer 122 (see FIG. 1B). The second conductive layer 122 is disposed on the substrate 121 and electrically connected to the first conductive layer 111 of the circuit board 11. The second conductive layer 122 comprises at least one conductive circuit (or conductive layer), which can be electrically connected to the first conductive layer 111 of the circuit board 11. In addition, as shown in FIG. 1A, the substrate 121 defines a substrate area DA. In this embodiment, the term “substrate area DA” indicates a projection area of the substrate 121 projected on the circuit board 11. In addition, the scale of each substrate 121 is defined as one substrate width in each direction (e.g., the direction D1 or D2). For the sake of easy understanding, the scale of the substrate 121 is defined as the substrate width in the direction D1, and the substrate width (the substrate width Dx) is not greater than 10 mm (Dx≤10 mm), such as 7 mm, 8 mm, or 10 mm. Herein, the term “scale” indicates the dimension of a simple geometric width, height and depth, and the “maximum value of scale” indicates the maximum value is confirmed from the simple geometric width, height, and depth. In some embodiments, the substrate width (the substrate width Dx) is, for example, 1 mil (1 mil=0.0254 mm), 3 mil, 0.035 mm, 0.1 mm, 5 mil, 0.4 mm, 0.46 mm, 0.5 mm, 0.8 mm, 1.5 mm, 3 mm, 5 mm, 10 mm, or the likes.

In this embodiment, the carrier board 12 could be is a surface mounted device (SMD). The conductive members 15 are disposed corresponding to the conductive pads of the corresponding carrier boards 12, and located between the circuit board 11 and the corresponding carrier boards 12, so that the conductive members 15 can electrically connect the corresponding carrier boards 12 to the circuit board 11. In this embodiment, each carrier board 12 is electrically connected to the first conductive layer 111 of the circuit board 11 via four conductive members 15, so that the second conductive layer 122 of the carrier board 12 can be electrically connected to the first conductive layer 111 of the circuit board 11. Herein, the carrier board 12 can comprise a plurality of conductive pads corresponding to the conductive members 15, respectively. In some embodiments, each conductive member 15 can connect the top surface of the circuit board 11 to the top surface of the carrier board 12 for electrically connecting the carrier board 12 to the circuit board 11 via the conductive members 15. In some embodiments, the conductive members 15 can be jumpers configured inside the carrier board 12 or side jumpers configured on the edges of the carrier board 12 for electrically connecting the carrier board 12 to the circuit board 11. In some embodiments, the conductive members 15 comprise conductive materials (e.g., copper paste, silver paste, solder paste, or ACP), which can be disposed in the through holes inside the carrier board 12, or configured on the edges of the carrier board 12 for electrically connecting the carrier board 12 to the circuit board 11. In addition, in some embodiments, an additional conductive member (not shown) can be provided between two adjacent carrier boards 12, and the additional conductive member can electrically connect the adjacent two carrier boards 12 and be electrically connected to the circuit board 11. These configurations can increase the application flexibility. In some embodiments, each carrier board 12 is electrically connected to the first conductive layer 111 of the circuit board 11 by laser beams so as to form eutectic bonding without the conductive members 15.

The shape of the above-mentioned circuit board 11 or the carrier board 12 is not limited to a polygon (e.g., rectangle or square), and it can also be a circle, an ellipse, or an irregular shape. This disclosure is not limited. In some embodiments, multiple carrier boards 12 can be arranged in a row, a column, or a matrix including rows and columns (referring to the embodiment of FIG. 2) according to requirements, or arranged in any of other shapes. In this embodiment, the multiple carrier boards 12 are arranged as a two-dimensional matrix including rows and columns, so that the electronic device 1 can function as an active matrix (AM) electronic device, such as for example but not limited to, an AM LED display device, an AM Mini LED display device, an AM Micro LED display device, an AM sensor array, an AM antenna array, an AM laser array, an AM projection array, or an AM millimeter-wave radar array.

In addition, the circuit board 11 and the substrate 121 can be transparent, which is non-opaque such as crystal clear or translucent, or opaque, and each of them can be a rigid substrate or a flexible substrate. In this case, both of the circuit board 11 and the substrate 121 are transparent. The material of the circuit board 11 or the substrate 121 can comprise glass, resin, metal, ceramics, or composite materials. Herein, the resin material is a flexible material, and can comprise organic polymer material. The glass transition temperature (Tg) of the organic polymer material is, for example, between 250° C. and 600° C., and preferably between 300° C. and 500° C. Since the organic polymer material has a relative higher glass transition temperature, the following thin-film processes can be performed directly to form various components (e.g., the thin-film transistors), the conductive layers or wires. The organic polymer material can be a thermoplastic material, such as polyimide (PI), polyethylene (PE), polyvinylchloride (PVC), polystyrene (PS), acrylic, fluoropolymer, polyester, nylon, and the like. In some embodiments, the circuit board 11 may be a transparent or/and flexible circuit board (the material includes PI, for example). In some embodiments, the substrate 121 may be a transparent or/and flexible substrate (the material is, for example, PI). In some embodiments, the circuit board 11 can be a transparent and/or flexible circuit board (e.g., made of PI). In some embodiment, the substrate 121 can be a transparent and/or flexible substrate (e.g., made of PI). In some embodiments, the circuit board 11 and the substrate 121 are transparent and flexible so as to achieve the double-sided light transmission characteristics. For example, when the photoelectric element 13 is a Mini LED or a Micro LED, the electronic device 1 can become a flexible display device with double-sided light transmission.

Moreover, the first conductive layer 111 or the second conductive layer 122 comprises a copper conductive layer made of copper material. In some embodiments, both of the first conductive layer 111 and the second conductive layer 122 comprises the copper conductive layer. Different from the conventional transparent conductive layer, such as the conductive layer made of indium tin oxide (ITO), the line width of conductive layer made of copper metal can be formed relatively narrower. Thus, the component distance Px can also be relatively smaller, so that the transmittance of the electronic device 1 is relatively higher, and it is more suitable for fabricating a display device with high resolution and double-sided light transmission. For example, in the case that the component distance Px is 10 mm (i.e., the unit area PA is 10 mm*10 mm) and the substrate width is 7 mm (i.e., the substrate area DA is 7 mm*7 mm), when the circuit board 11 is a transparent circuit board and adopts a copper conductive layer (wherein the line width of copper conductive layer is extremely small and can be ignored), and the substrate 121 is an opaque substrate, the light shielding rate of each unit is about 49% (i.e., the light transmittance is greater than or equal to 51%). In other words, when the substrate 121 is a transparent substrate, the light transmittance of each unit will be much higher than 51%.

A plurality of photoelectric elements 13 are respectively disposed on the carrier boards 12 and electrically connected to the second conductive layers 122 of the carrier boards 12. Each carrier board 12 is defined with two opposite surfaces (i.e., the first surface S1 and the second surface S2 as shown in FIG. 1B). In this embodiment, one of the surfaces of the carrier board 12, which is not configured with the photoelectric elements 13 (i.e., the second surface S2 that is the lower surface of the carrier board 12), is configured to face toward the circuit board 11. To be noted, this disclosure is not limited thereto. In different embodiments, the surface, which is not configured with the photoelectric elements 13 (i.e., the first surface S1 that is the upper surface of the carrier board 12), can be configured to face toward the circuit board 11 (that is, the photoelectric element 13 is disposed in a flip-chip mode), and this disclosure is not limited thereto.

Referring to FIG. 1A, the photoelectric element 13 defines an element area dA. Herein, the “element area dA” indicates the projection area of the photoelectric element 13 projected on the substrate 121. The ratio of the above-mentioned substrate area DA to the element area dA can be not less than 5 (i.e., DA/dA≥5). For example, the substrate area DA is 0.16 mm² (0.4 mm*0.4 mm), and the element area dA is 0.0096774 mm² ((3*0.0254) mm*(5*0.0254) mm), so DA/dA>16.53. In another example, the substrate area DA is 0.64 mm² (0.8 mm*0.8 mm), and the element area dA is 0.0290322 mm² ((5*0.0254) mm*(9*0.0254) mm), so DA/dA>22.04. In yet another example, the substrate area DA is 0.16 mm² (0.4 mm*0.4 mm), and the element area dA is 0.0290322 mm² ((5*0.0254) mm*(9*0.0254) mm), so DA/dA>5.51.

In some embodiments, the ratio of the above-mentioned substrate area DA to the element area dA can be not less than 50 (i.e., DA/dA≥50). For example, the substrate area DA is 0.16 mm² (0.4 mm*0.4 mm), and the element area dA is 0.0018 mm² (0.03 mm*0.06 mm), so DA/dA=88.88. In another example, the substrate area DA is 0.64 mm² (0.8 mm*0.8 mm), and the element area dA is 0.0096774 mm² ((3*0.0254) mm*(5*0.0254) mm), so DA/dA>66.13. In some embodiments, the ratio of the substrate area DA to the element area dA can be not less than 100 (i.e., DA/dA 100). For example, the substrate area DA is 0.2116 mm² (0.46 mm*0.46 mm), and the element area dA is 0.0018 mm² (0.03 mm*0.06 mm), so DA/dA=117.56. The above numerical values are only examples, and are not to limit the scope of this disclosure.

In addition, similar to the carrier board 12, the scale of each photoelectric element 13 is defined as one element width in each direction (e.g., the direction D1 or D2). For the sake of easy understanding, the element width dx is defined in the direction D1, and the element width (the element width dx) is not greater than 80 mil (dx≤80 mil). In some embodiments, the element width (the element width dx) is not greater than 12 mil (dx≤12 mil). In some embodiments, the element width (the element width dx) is not less than 0.005 mm (dx≥0.005 mm), such as 0.008 mm, 0.01 mm, 3 mil, 4 mil, 5 mil, 7 mil, or the likes.

In this embodiment, the number of photoelectric elements 13 configured on each carrier board 12 is three, but this disclosure is not limited thereto. In some embodiments, the photoelectric element 13 can comprise at least one photoelectric chip, pyroelectric chip, piezoelectric chip, or sensor chip. In some embodiments, the photoelectric element 13 can be, for example but not limited to, an LED chip, a Mini LED chip, a Micro LED chip or the package thereof, or a light-emitting chip or package with unlimited dimensions in millimeters, micrometers, or smaller. In some embodiments, each carrier board 12 can have a group of photoelectric elements, and each group of photoelectric elements can comprise at least one photoelectric element 13, so that each carrier board 12 is realized as a single pixel. In some embodiments, each carrier board 12 can comprise multiple groups of photoelectric elements, and each group of photoelectric elements can comprise at least one photoelectric element 13, so that it can be realized that each carrier board 12 comprises a plurality of pixels. In some embodiments, the photoelectric element 13 can comprise, for example, red, blue, or green LED, Mini LED, or Micro LED chips, or any of other colors of LED, Mini LED, or Micro LED chip. When the three photoelectric elements 13 on the carrier board 12 are respectively red, blue and green LED, Mini LED, or Micro LED chips, thereby forming a full-color LED, Mini LED, or micro LED display device. The above-mentioned chip can be a die with horizontal electrodes, flip-chip electrodes, or vertical electrodes, which are electrically connected to the second conductive layer 122 of the carrier board 12 by wire bonding or flip-chip bonding. In some embodiments, the electronic device can further comprise a signal layer of sealing member or a plurality of sealing members (not shown), which can be disposed on the carrier boards 12 and cover the photoelectric elements 13 as well as the carrier boards 12, thereby protecting the photoelectric elements 13 from the damage caused by the environmental moisture or dusts.

A plurality of driving elements 14 are respectively disposed on the circuit board 11 or the carrier boards 12, and the driving elements 14 are electrically connected the first conductive layer 111 to the second conductive layers 122 respectively, and drive the photoelectric elements 13. As shown in FIG. 2, the driving elements 14 of this embodiment are disposed on the carrier boards 12. Herein, one driving element 14 is arranged corresponding to one carrier board 12, and the driving elements 14 are electrically connected to the second conductive layer 122 of the carrier board 12 and the first conductive layer 111 of the circuit board 11. Accordingly, the circuit board 11 can transmit the driving signals to the driving elements 14 on the carrier boards 11 through the first conductive layer 111 and the conductive members 15, so that the driving element 14 can drive three photoelectric elements 13 through the second conductive layer 122. In different embodiments, when a plurality of driving elements 14 are distributed on the circuit board 11, each driving element 14 can drive the corresponding photoelectric element 13 via the first conductive layer 111, the conductive member 15 and the second conductive layer 122 of the carrier board 12. Each driving element 14 can include at least one thin-film transistor (TFT). In some embodiments, in addition to the thin-film transistor, each driving element 14 can further comprise additional thin-film elements or circuits, such as thin-film resistors, capacitors, or insulating film layers. The configuration of the driving element 14 depends on the driving mode of the photoelectric element 13, and this disclosure is not limited. In some embodiments, each driving element 14 can be a semiconductor IC, such as a silicon-based semiconductor IC, and arranged on the carrier board 12 or the circuit board 11.

Referring to FIG. 1A, the electronic device 1 of this embodiment is further defined with a plurality of units on the circuit board 11 (FIG. 1A shows four units, and one unit can be one pixel in this embodiment), and these units are arranged in a two-dimensional array. Herein, each unit includes a carrier board 12, and three photoelectric elements 13 and a driving element 14 on the carrier board 12. In this case, the circuit board 11 further defines a unit area PA (FIG. 1A shows four unit areas PA, and the unit area can be, for example, a pixel area). In some embodiments, the ratio of the substrate area DA to the unit area PA can be at least less than 0.5 (i.e., DA/PA<0.5).

Referring to FIGS. 1A to 2, in the electronic device 1 of some embodiments, the ratio of the component distance Px to the substrate width Dx can be greater than or equal to 1, and less than or equal to 400 (1≤Px/Dx≤400), and the ratio of the substrate width Dx to the element width dx can be greater than or equal to 1, and less than or equal to 2000 (1≤Dx/dx≤2000). In some embodiments (wherein a square is considered in area calculation for example), when the ratio of the component distance Px to the substrate width Dx is greater than 7 (Px/Dx>7), the transmittance of the electronic device 1 can be greater than 49%, which is benefit in fabricating a display device with double-sided light transmission. In some embodiments, when the component distance Px is equal to 10 mm and the substrate width Dx is equal to 0.4 mm (i.e., Px/Dx is equal to 40), the light shielding rate of the electronic device is about 0.16%, and the transmittance thereof can reach 98.4%. In some embodiments, when the component distance Px is equal to 10 mm and the substrate width Dx is equal to 0.1 mm (i.e., Px/Dx is equal to 100), the light shielding rate of the electronic device is about 0.01%, and the transmittance thereof can reach 99.9%.

As mentioned above, the electronic device 1 of this embodiment comprises a circuit board 11, a plurality of carrier boards 12, a plurality of photoelectric elements 13, and a plurality of driving elements 14 (as well as a plurality of conductive members 15). Due to the arrangements and connections of the circuit board 11, the carrier boards 12, the photoelectric elements 13, and the driving components 14, as well as the feature that the ratio of the substrate area DA to the element area dA is not less than 5, the electronic device 1 of this embodiment has the application flexibility for reflecting the requirements of users, so that it can be suitable for various product requirements.

To be noted, each of the unit area PA, the substrate area DA, and the element area dA in the foregoing embodiments is calculated and considered as a square, but this disclosure is not limited thereto.

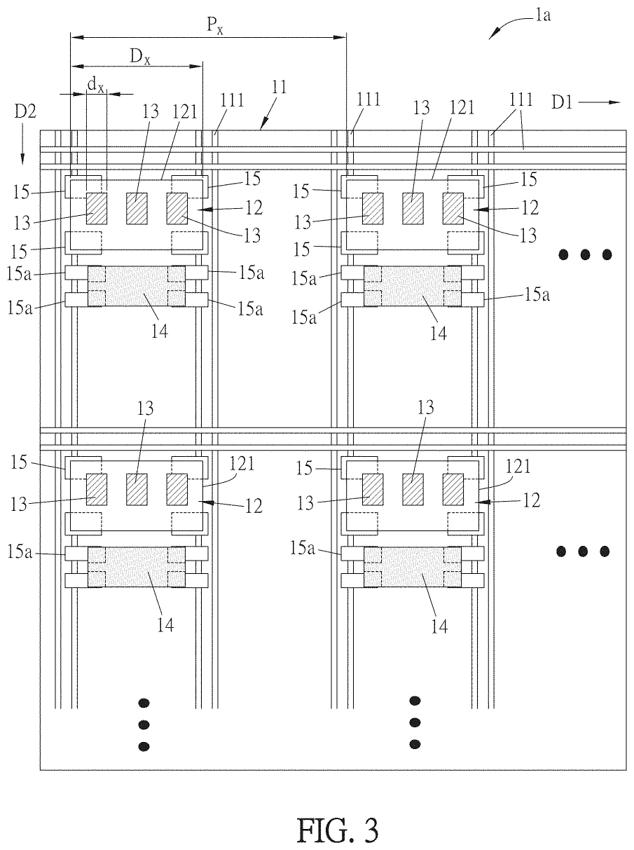

FIG. 3 is a schematic diagram showing an electronic device according to another embodiment of this disclosure. Different from the electronic device 1 of FIG. 2, the electronic device 1a of this embodiment as shown in FIG. 3 comprises a plurality of driving element 14 disposed on the circuit board 11. Each driving element 14 is disposed adjacent to one corresponding carrier board 12, so that the driving elements 14 can drive the photoelectric elements 13 disposed on the corresponding carrier boards 12, respectively. In this embodiment, each driving element 14 is a surface mounted device, which is electrically connected to the first conductive layer 111 of the circuit board 11 via, for example, four conductive members 15a. For example, the conductive members 15a can be conductive pads, and each driving element 14 has corresponding conductive pads. In different embodiments, the driving element 14 can be formed on the circuit board 11 by, for example, thin-film process, electrically connected to the first conductive layer 111 and the second conductive layer 122, and driving the photoelectric element 13. This disclosure is not limited thereto.

In addition, the driving elements 14 and the carrier boards 12 of this embodiment are respectively disposed on the same surface (i.e., the upper surface) of the circuit board 11. In different embodiments, the driving elements 14 and the carrier boards 12 can be disposed on the opposite surfaces of the circuit board 11, respectively, and this disclosure is not limited. For example, the carrier boards 12 are disposed on the upper surface of the circuit board 11, but the driving elements 14 are disposed on the lower surface of the circuit board 11.

In summary, the electronic device of this disclosure comprises a circuit board, a plurality of carrier boards, a plurality of photoelectric elements, and a plurality of driving elements. Due to the arrangements and connections of the circuit board, the carrier boards, the photoelectric elements and the driving components, as well as the feature that the ratio of the substrate area to the element area is not less than 5, the electronic device of this disclosure has the application flexibility for reflecting the requirements of users, so that it can be suitable for, not only the benefit of the high light-transmittance display but also various product requirements.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. An electronic device, comprising:
a circuit board having a first conductive layer;
a plurality of carrier boards arranged on the circuit board with a component distance in a direction, wherein each of the carrier boards has a substrate and a second conductive layer, the second conductive layer is disposed on the substrate and electrically connected to the first conductive layer of the circuit board, and the substrate defines a substrate area;
a plurality of photoelectric elements disposed on the carrier boards and electrically connected to the second conductive layers of the carrier boards, wherein each of the photoelectric elements defines an element area, and a ratio of the substrate area to the element area is not less than 5; and
a plurality of driving elements disposed on the circuit board or the carrier boards, wherein the driving elements are electrically connected to the first conductive layer and the second conductive layers, and drive the photoelectric elements.

2. The electronic device of claim 1, wherein the ratio of the substrate area to the element area is not less than 50.

3. The electronic device of claim 1, wherein the ratio of the substrate area to the element area is not less than 100.

4. The electronic device of claim 1, wherein a scale of each of the substrates is defined as one substrate width, and the substrate width is not greater than 10 mm.

5. The electronic device of claim 4, wherein the substrate width is not greater than 5 mm.

6. The electronic device of claim 4, wherein the substrate width is not less than 1 mil.

7. The electronic device of claim 1, wherein a scale of each of the photoelectric elements is defined as one element width, and the element width is not greater than 80 mil.

8. The electronic device of claim 7, wherein the element width is not greater than 12 mil.

9. The electronic device of claim 7, wherein the element width is not less than 0.005 mm.

10. The electronic device of claim 1, wherein the component distance is not greater than 10 mm.

11. The electronic device of claim 10, wherein a scale of each of the substrates is defined as one substrate width, the substrate width is not greater than 10 mm, and a ratio of the component distance to the substrate width is greater than or equal to 1 and less than or equal to 400.

12. The electronic device of claim 11, wherein the ratio of the component distance to the substrate width is greater than 7.

13. The electronic device of claim 1, wherein a scale of each of the substrates is defined as one substrate width, a scale of each of the photoelectric elements is defined as one an element width, and a ratio of the substrate width to the element width is greater than or equal to 1 and less than or equal to 2000.

14. The electronic device of claim 1, wherein the circuit board is a transparent, or/and a flexible circuit board; or the substrate is a transparent, or/and a flexible substrate.

15. The electronic device of claim 1, wherein the first conductive layer, or/and the second conductive layer comprises a copper conductive layer.

16. The electronic device of claim 1, wherein each of the driving elements comprises at least a thin-film transistor, or a semiconductor IC.

17. The electronic device of claim 1, further comprising:
a plurality of conductive members electrically connecting the carrier boards to the circuit board.

18. The electronic device of claim 17, wherein each of the conductive members is located between the circuit board and the corresponding carrier board; or each of the conductive members connects a top surface of the circuit board and a top surface of the corresponding carrier board.

19. The electronic device of claim 1, wherein each of the carrier boards is defined with two surfaces opposite to each other, and one of the two surfaces configured with the photoelectric elements faces toward the circuit board.

20. The electronic device of claim 1, wherein the driving elements and the carrier boards are disposed on two opposite surfaces of the circuit board, respectively.
